(19) United States
(12) Patent Application Publication
(10) Pub. No.: US 2025/0218749 A1
(43) Pub. Date: Jul. 3, 2025

(54) APPARATUS OF PROCESSING A SUBSTRATE AND METHOD OF PROCESSING A SUBSTRATE

(71) Applicant: SEMES CO., LTD., Cheonan-si (KR)

(72) Inventors: Ki Hoon CHOI, Cheonan-si (KR); Hyeong Soo PARK, Yongin-si (KR); Seung Un OH, Cheonan-si (KR); Jin Yeong SUNG, Hwaseong-si (KR); Seryeyohan CHO, Daejeon (KR); Sang Hyeon RYU, Yangpyeong (KR); Dong Geun LEE, Yongin-si (KR); Tae Shin KIM, Suwon-si (KR); Young Dae CHUNG, Incheon (KR)

(73) Assignee: SEMES CO., LTD., Cheonan-si (KR)

(21) Appl. No.: 19/001,982

(22) Filed: Dec. 26, 2024

(30) Foreign Application Priority Data
Dec. 29, 2023 (KR) 10-2023-0197495

(51) Int. Cl. H01J 37/32; B23K 26/352; G02B 26/08

(52) U.S. Cl. CPC H01J 37/32889; B23K 26/352; G02B 26/0833; H01J 37/32568; H01J 37/32834; H01J 2237/334

(57) ABSTRACT

The present invention provides an apparatus of processing a substrate. The apparatus of processing a substrate includes: a chamber providing a treatment space; a substrate supporting unit provided in the treatment space; a gas supply unit introducing gas into the treatment space; a plasma source providing energy that excites the gas introduced in the treatment space using plasma; an exhaust unit exhausting an atmosphere in the treatment space out of the treatment space; and a laser emission unit disposed above the supporting unit and emitting a laser beam to a substrate placed on the supporting unit, wherein the laser emission unit includes: a laser source generating the laser beam; and a Digital Micro-mirror Device (DMD) unit that is a light modulation unit modulating the laser beam generated from the laser source, wherein the DMD unit includes: micromirrors provided to be rotatable; and a board substrate on which the micromirrors are installed.

### CROSS-REFERENCE TO RELATED APPLICATIONS

This application claims priority to and the benefit of Korean Patent Application No. 10-2023-0197495 filed in the Korean Intellectual Property Office on Dec. 29, 2023, the entire contents of which are incorporated herein by reference.

### TECHNICAL FIELD

The present invention relates to an apparatus of processing a substrate and a method of processing a substrate, in more detail, an apparatus and method of processing a substrate using plasma.

### BACKGROUND ART

Plasma can be used in a treatment process of substrates. For example, plasma can be used in an etching, deposition, or dry cleaning process. Plasma is formed by a very high temperature, a strong electric field, or a high-frequency (RF) electromagnetic field, and plasma refers to an ionized gas state composed of ions, electrons, radicals, etc. A dry cleaning, ashing, or etching process that uses plasma is performed by reaction or collision of the ions or radial particles included in the plasma with a substrate.

Further, in order to manufacture a semiconductor device, various heat treatments such as modification and annealing with a semiconductor wafer are repeated. Further, the specifications of semiconductor devices are becoming increasingly difficult every year as they undergo higher density, multi-layering, and greater integration. As a result, improvement in uniformity and film quantity within the various heat-treated semiconductor wafer surfaces are required.

In a process of treating a substrate using plasma, a method of inducing reaction and removing a thin film by heating the entire of a substrate is used. In particular, the method of heating a substrate by emitting a laser beam to the substrate is used to perform an atomic layer etching (ALE) process. However, when a substrate is heated by emitting a laser beam to the entire region of the substrate in the related art, it is impossible to differently transmit heat energy to regions of the substrate and heat is uniformly transmitted to the entire region of the substrate, so there is a problem that even though the thickness of the thin film of a substrate is different in regions, it is difficult to perform asymmetric etching and selectively etch local regions.

### SUMMARY OF THE INVENTION

An objective of the present invention is to provide an apparatus of processing a substrate and a method of processing a substrate, the apparatus and method being able to effectively treat a substrate.

Further, an objective of the present invention is to provide an apparatus of processing a substrate and a method of processing a substrate, the apparatus and method being able to adjust the amount of heat for heating in each local region of a substrate and adjust the etching amount.

Further, an objective of the present invention is to provide an apparatus of processing a substrate and a method of processing a substrate, the apparatus and method being able to perform etching such that a uniform thin film is formed on a substrate by selectively heating the substrate.

The objectives of the present invention are not limited thereto and other objectives not stated herein may be clearly understood by those skilled in the art from the following description. The present invention provides an apparatus of processing a substrate. The apparatus of processing a substrate includes: a chamber providing a treatment space; a substrate supporting unit provided in the treatment space; a gas supply unit introducing gas into the treatment space; a plasma source providing energy that excites the gas introduced in the treatment space using plasma; an exhaust unit exhausting an atmosphere in the treatment space out of the treatment space; and a laser emission unit disposed above the supporting unit and emitting a laser beam to a substrate placed on the supporting unit, wherein the laser emission unit includes: a laser source generating the laser beam; and a Digital Micro-mirror Device (DMD) unit that is a light modulation unit modulating the laser beam generated from the laser source, wherein the DMD unit includes: micromirrors provided to be rotatable; and a board substrate on which the micromirrors are installed.

In an embodiment, the laser emission unit may further include an imaging unit adjusting and emitting the laser beam modulated by the DMD unit to the substrate to correspond to an area to which the laser beam is emitted.

In an embodiment, the laser emission unit may further include a beam shaper converting the type of the laser beam generated by the laser source, and the beam shaper may convert the type of the laser beam and then transmits the laser beam to the DMD unit.

In an embodiment, the apparatus may further include: a window provided on a top of the chamber; an upper electrode stacked on the window; a lower electrode provided lower than the substrate; and a high-frequency power supply connected with any one or more of the upper electrode and the lower electrode, wherein the upper electrode may be a transparent electrode, and the laser emission unit may be provided above the window.

In an embodiment, the window may be made of a quartz material.

In an embodiment, the apparatus may further include a control unit, wherein the control unit may control each of the micromirrors of the DMD unit to selectively switch an On state in which each of the micromirror reflects the laser beam to the substrate and an Off state in which each of the micromirror dumps the laser beam so that heat energy required for each region of the substrate can be transmitted by emitting the laser beam to the substrate.

In an embodiment, the control unit may perform control to perform a removing step in which the gas supply unit introduces a process gas into the treatment space, the plasma source excites the introduced process gas with plasma, and then the laser emission unit heats the substrate by emitting the laser beam to the substrate.

In an embodiment, in the removing step, the laser emission unit may emit the laser beam to an entire region of the substrate and the DMD unit may form different emission patterns of the laser beam that is emitted to each of local regions of the substrate such that the amount of heat that heats each of the regions of the substrate is selectively adjusted.

In an embodiment, in the removing step, the emission pattern of the laser beam may be formed by reflecting thickness data for each of the regions of the substrate.

Further, the present invention provides a method of processing a substrate. The method of processing a substrate, a substrate is provided supported on a substrate supporting unit comprising a lower electrode within and provided in a chamber providing a treatment space, the method performs a removing step in which a process gas is introduced to the treatment space, the process gas is excited with plasma by applying high-frequency power, and a laser emission unit heats the substrate by emitting a laser beam to the substrate, wherein the removing step includes: a laser modulation step of forming an emission pattern by modulating the laser beam by means of a light modulation unit included in the laser emission unit; and a laser emission step of emitting the laser beam modulated by the light modulation unit to the substrate.

In an embodiment, the light modulation unit may be a Digital Micro-mirror Device (DMD) unit, and the DMD unit may form different emission patterns of a laser beam that is emitted to each of local regions of the substrate, thereby selectively adjusting the amount of heat that heats each of the regions of the substrate.

In an embodiment, the DMD unit may include micromirrors provided to be rotatable, and an emission pattern may be formed, in the laser modulation step, by selectively switching an On state in which each of the micromirrors reflects the laser beam to the substrate and an Off state in which each of the micromirrors dumps the laser beam, by adjusting a direction in which the micromirrors each reflect the laser beam.

In an embodiment, the laser beam modulated by the DMD unit may be adjusted into the size corresponding to the substrate and then emitted to the substrate by the laser emission unit, and the emission pattern, in the removing step, may be formed by reflecting thickness data for each of the regions of the substrate.

In an embodiment, the method may perform a modification step of treating the substrate by introducing a treatment gas into the treatment space and exciting the treatment gas with plasma; and a first purge step of introducing a purge gas into the treatment space and exhausting the treatment space; before the removing step, and the method may perform a second purge step of introducing a purge gas into the treatment space and exhausting the treatment space after the removing step; and the modification step, the first purge step, the removing step, and the second purge step may be sequentially performed.

In an embodiment, the laser beam may be transmitted to the substrate through an upper electrode provided on a top of the chamber; the upper electrode may include a window made of quartz and a transparent electrode stacked on the window; and the high-frequency power may be applied to any one or more of the transparent electrode and the lower electrode.

Further, the present invention provides an apparatus of processing a substrate. The apparatus of processing a substrate includes: a chamber providing a treatment space; a substrate supporting unit provided in the treatment space; a gas supply unit introducing gas into the treatment space; a plasma source providing energy that excites the gas introduced in the treatment space using plasma; an exhaust unit exhausting an atmosphere in the treatment space out of the treatment space; a window provided on a top of the chamber; an upper electrode stacked on the window; a lower electrode provided lower than the substrate; a high-frequency power supply connected with any one or more of the upper electrode and the lower electrode; and a laser emission unit disposed above the window and emitting a laser beam to a substrate placed on the supporting unit, wherein the laser emission unit includes: a laser source generating the laser beam; and a Digital Micro-mirror Device (DMD) unit that is a light modulation unit modulating the laser beam generated from the laser source; an imaging unit adjusting and emitting the laser beam modulated by the DMD unit to the substrate to correspond to an area to which the laser beam is emitted; and a beam shaper converting the type of the laser beam generated by the laser source, wherein the DMD unit includes: micromirrors provided to be rotatable; and a board substrate on which the micromirrors are installed, and the upper electrode is a transparent electrode.

In an embodiment, the apparatus may further include a control unit, wherein the control unit may control each of the micromirrors of the DMD unit to selectively switch an On state in which each of the micromirror reflects the laser beam to the substrate and an Off state in which each of the micromirror dumps the laser beam so that heat energy required for each region of the substrate can be transmitted by emitting the laser beam to the substrate.

In an embodiment, the control unit may perform control to perform: a modification step in which the gas supply unit introduces a first process gas into the treatment space and the introduced first process gas is excited with plasma by controlling the plasma source, thereby treating the substrate; a first purge step in which the gas supply unit introduces a third process gas into the treatment space and the treatment space is exhausted by controlling the exhaust unit; a removing step in which the gas supply unit introduces a second process gas into the treatment space, the introduced second process gas is excited with plasma by controlling the plasma source, and then the laser emission unit heats the substrate by emitting the laser beam to the substrate; and a second purge step in which the gas supply unit introduces the third process gas into the treatment space and the treatment space is exhausted by controlling the exhaust unit, and the modification step, the first purge step, the removing step, and the second purge step may be sequentially performed.

In an embodiment, in the removing step, the laser emission unit may emit the laser beam to an entire region of the substrate and the DMD unit may form different emission patterns of the laser beam that is emitted to each of local regions of the substrate such that the amount of heat that heats each of the regions of the substrate is selectively adjusted.

In an embodiment, in the removing step, the emission pattern of the laser beam may be formed by reflecting thickness data for each of the regions of the substrate.

According to an embodiment of the present invention, it is possible to effectively process a substrate.

Further, according to an embodiment of the present invention, it is possible to adjust the amount of heating and the amount of etching for each of local regions of a substrate.

Further, according to an embodiment of the present invention, it is possible to perform etching such that a uniform thin film is formed on a substrate by selectively heating the substrate.

Effects of the present invention are not limited to those described above and effects not stated above will be clearly understood to those skilled in the art from the specification and the accompanying drawings.

### BRIEF DESCRIPTION OF THE DRAWINGS

FIG. 1 shows an apparatus of processing a substrate according to an embodiment of the present invention.

FIG. 2 is a view schematically showing the configuration of the laser emission module of FIG. 1.

FIG. 3 is a graph showing distribution of light that is output from a laser source and FIG. 4 is a graph showing distribution of light that has passed through a beam shaper.

FIG. 5 is a view schematically showing the appearance of a light modulation device.

FIG. 6 is a view showing that light is output from the light modulation device.

FIG. 7 is a view showing that light output from the light modulation device is removed at an optical dumber.

FIG. 8 is a view for explaining the principle that light is removed at an optical dumper.

FIG. 9 is a view for explaining an emission pattern of light that is output from the light modulation unit.

FIG. 10 is a view illustrating that an ALE process is performed and illustrating the state of the apparatus when an adsorption process is performed, as a use example of the apparatus of processing a substrate.

FIG. 11 is a view illustrating the state of the apparatus when the modification step of FIG. 10 is performed.

FIG. 12 is a view illustrating the state of the apparatus when the first purge step of FIG. 10 is performed.

FIG. 13 is a view illustrating the state of the apparatus when the removing step of FIG. 10 is performed.

FIG. 14 shows an embodiment of an emission pattern of a laser beam modulated in the laser modulation step of FIG. 10.

FIG. 15 is a view illustrating the state of the apparatus when the second purge step of FIG. 10 is performed.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

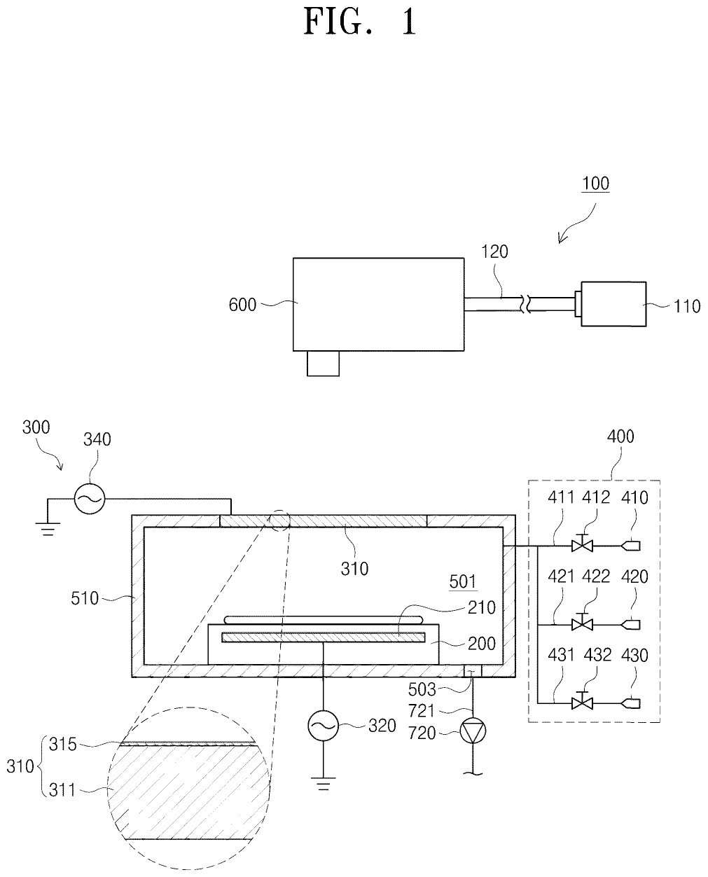

Hereafter, embodiments of the present invention are described with reference to FIG. 1 to FIG. 15.

FIG. 1 shows an apparatus of processing a substrate according to an embodiment of the present invention.

An apparatus 1000 for treating a substrate may include a process chamber 510, a supporting unit 200, a gas supply unit 400, a plasma source 300, and a laser emission unit 100. The apparatus 1000 for treating a substrate treats substrates W using plasma.

The process chamber 510 has an internal space 501 for performing a process therein. An exhaust hole 503 is formed through the bottom of the process chamber 510. The exhaust hole 503 is connected with an exhaust line in which a pump 720 is mounted. Reaction byproducts produced in a process and gas remaining in the internal space 501 are exhausted through the exhaust hole 503 by exhaust pressure that is applied by the pump 720. Further, the internal space 501 of the process chamber 510 is decreased in pressure to a desired pressure in the exhaust process. The pump 720 may be vacuum pump.

An opening (not shown) is formed through a side of the process chamber 510. The opening (not shown) functions as a passage through which substrates W are loaded and unloaded into and out of the process chamber 510. The opening (not shown) is opened and closed by a door assembly (not shown).

The supporting unit 200 is positioned in the lower region of the internal space 501. The supporting unit 200 may include an electrostatic chuck (ESC). The ESC clamps substrates W using electrostatic force. Unlike, the supporting unit 200 can support substrates W using various methods such as mechanical clamping. The supporting unit 200 may include a metallic lower electrode 210. The lower electrode 210 may be made of aluminum. The lower electrode 210 may be provided in a plate shape. Further, a channel may be formed in the supporting unit 200. The channel is provided as a passage through which cooling liquid circulates. The cooling liquid cools substrates W by absorbing heat of the substrates W through the supporting unit 200. The supporting unit 200 and substrates W can be cooled and the substrates W can be maintained at desired temperature by circulation of the cooling liquid.

The gas supply unit 400 supplies gas for a process to the internal space 501. The gas supply unit 400 includes a first gas supply line 411 connected with a first gas supply source 410, a second gas supply line 421 connected with a second gas supply source 420, and a third gas supply line 431 connected with a third gas supply source 430. A first gas and a second gas may be reaction gases for treating substrates and a third gas may be a purge gas for purge. A first valve 412 that opens the passage of the first gas supply line 411 or adjusts the flow rate of the fluid flowing through the passage may be installed in the first gas supply line 411. A second valve 422 that opens the passage of the second gas supply line 421 or adjusts the flow rate of the fluid flowing through the passage may be installed in the second gas supply line 421. A third valve 432 that opens the passage of the third gas supply line 431 or adjusts the flow rate of the fluid flowing through the passage may be installed in the third gas supply line 431.

The plasma source 300 generates plasma from a process gas remaining in a discharge space. The discharge space may be the region over the supporting unit 200 in the process chamber 510. The plasma source 300 may have capacitive coupled plasma. The plasma source 300 may include an upper electrode 315, the lower electrode 210 of the supporting unit 200, a first high-frequency power supply 320, and a second high-frequency power supply 330. The upper electrode 315 and the lower electrode 210 may be provided opposite to each other in the up-down direction.

The upper electrode 315 is stacked on a window 311. The upper electrode 315 is coated on the window 311. The upper electrode 315 is configured such that a laser beam that is applied from the laser emission unit 100 can be transmitted to a substrate W without a loss (or with a loss minimized). The upper electrode 315 is a transparent electrode. The upper electrode 315 may be an indium tin oxide (ITO). Further, the upper electrode 315 may be any one of AZO, FTO, ATO, SnO₂, ZnO, IrO₂, RuO₂, graphene, metal nanowire, and CNT or a mixture thereof or may be formed by multiple stacking. The upper electrode 315 is provided with a first thickness or less. The first thickness is a thickness that allows light or microwaves to pass through the determined material. The first thickness depends on the material that is determined for the upper electrode 315. By “allowing transmission” in this description, it means that it does not significantly affect the permeability. For example, when the upper electrode 315 is ITO, the first thickness may be 1 μm. The upper electrode 315 and the lower electrode 210 are combined, thereby generating an electric field by an RF voltage that is applied to any one or more. According to an example, the upper electrode 315 may be grounded and high-frequency power may be applied to the lower electrode 210 by the first high-frequency power supply 320. Selectively, power by the second high-frequency power supply 330 may be applied to the upper electrode 315 and the lower electrode 210 may be grounded. Further, selectively, high-frequency power may be applied to both of the upper electrode 315 and the lower electrode 210.

The window 311 is provided in a disc shape. The window 311 is made of a material that can transmit a laser beam for heating substrates W. Further, the window 311 is made of a material having corrosion resistance. Quartz may be provided as an example of the window 311.

The laser emission unit 100 can emit a laser beam to substrates W.

A laser beam transmitted through the laser emission unit 100 heats a substrate W on the supporting unit 20.

The temperature of the region of a substrate W to which the laser beam emitted by the laser emission unit 100 is emitted can be increased. Accordingly, the region emitted with a laser beam can be relatively more etched and the region not emitted with a laser beam can be relatively less etched.

According to an embodiment of the present invention, a laser beam is emitted to the entire region of the surface of a substrate W, whereby the entire region of the surface of the substrate W is simultaneously heated. Further, the emission amount of a laser beam is adjusted for each region of a substrate W, whereby it is possible to heat the regions of the substrate W to different temperatures. The laser beam may be large-area laser beam fitted to the size of substrates. That is, the laser beam can be emitted to the entire region of a substrate W. The laser emission unit 100 can heat the entire substrate W at a time by emitting a laser beam at a time to the entire region that needs to be heated of the region of the substrate W.

Hereafter, the laser emission unit 100 is described in more detail.

The laser emission unit 100 includes a laser source 410, a laser transmission member 120, and a laser emission module 600.

The laser source 110 can generate light. The laser source 110 can generate light having straightness. The light generated by the laser source 110 can be emitted to a substrate W and can heat the substrate W. The light may be a laser beam, a fiber laser, a laser diode, or the like. Hereafter, it is exemplarily described that light is a laser beam L. The laser source 110 may have power of a range within 20 W per unit area (cm²). When the laser source 110 has power of a range within 20 W per unit area (cm²), a light modulation device 642 to be described below can be appropriately driven without being damaged.

The laser beam is a beam having a wavelength band that is not absorbed into the upper electrode 315. In an embodiment, the laser beam may have a wavelength of 500 nm to 550 nm.

The laser transmission member 120 transmits the laser beam generated by the laser source 110 to the laser emission module 600 without a loss. The laser source 110 and the laser emission module 600 are optically connected by the laser transmission member 120. According to an example, the laser transmission member 120 may be an optical fiber.

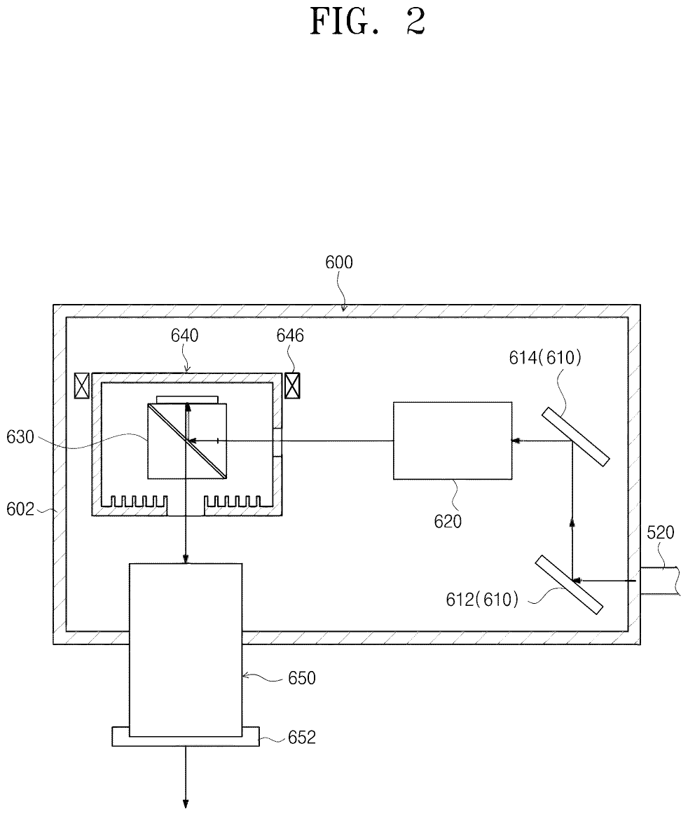

FIG. 2 is a view schematically showing the configuration of the laser emission module of FIG. 1.

The laser emission module 600 includes a housing 602, a mirror 610, a beam shaper 620, a prism optical device 630, a light modulation unit 640, and an imaging unit 650.

The housing 602 protects the mirror 610, the beam shaper 620, the prism optical device 630, the light modulation unit 640, and the imaging unit 650 by accommodating them in an internal space. The housing 602 may be fixedly installed over the process chamber 510. That is, the laser emission module 600 may be fixedly installed over the process chamber 510.

The mirror 610 reflects and transmits a laser beam traveling into the laser emission module 600 through the laser transmission member 120 to the beam shaper 620. The mirror 610 may include a plurality of mirrors to appropriately reflect the path of the laser beam. For example, the mirror 610 may include a first mirror 612 and a second mirror 614.

The beam shaper 620 can change the type of the light that is output from the laser source 110.

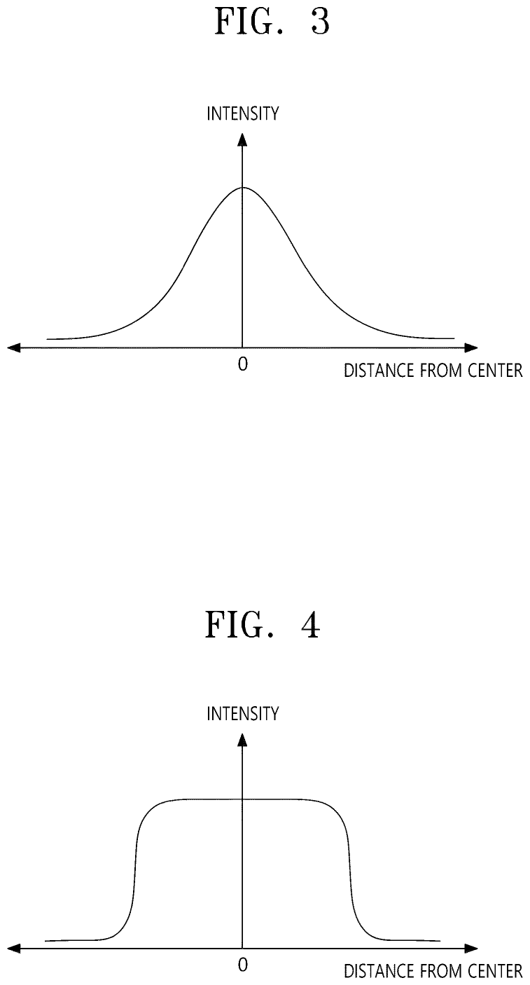

FIG. 3 is a graph showing distribution of light that is output from a laser source and FIG. 4 is a graph showing distribution of light that has passed through a beam shaper.

Referring to FIG. 2 to FIG. 4, the laser beam that is output from the laser source 110, as shown in FIG. 4, may have a Gaussian type in which the intensity distribution has Gaussian distribution. In more detail, the intensity of the laser beam that is output from the laser source 110 may be high at the center of the laser beam and the intensity (strength) thereof may gradually decrease as it goes away from the center of the laser beam (see FIG. 3). Accordingly, when the laser beam that is output from the laser source 110 is emitted to a substrate W, the region close to the center of the laser beam can be more heated and the region close to the edge of the laser beam can be less heated. Accordingly, in the laser emission module 600 according to an embodiment of the present invention, the beam shaper 620 may be disposed on the traveling path of the laser beam output from the laser source 110. The beam shaper 620 can change a Gaussian-type laser beam that is output from the laser source 110 into a flat top-type laser beam. The laser beam that is output from the laser source 110 can be converted into a flat top type having flat top distribution, in which the intensity (luminance) distribution is relatively uniform, through the beam shaper 620 (see FIG. 4).

Referring to FIG. 2 again, the laser beam that has passed through the beam shaper 620 can be transmitted to the prism optical device 630.

The prism optical device 630 can reflect the laser beam that has passed through the beam shaper 620 back to the light modulation unit 640. The laser beam transmitted to the light modulation unit 640 can be modulated at the light modulation unit 640 and then output. The laser beam modulated and output from the light modulation unit 640 can be transmitted to the imaging unit 650 through the prism optical device 530.

The light modulation unit 640 can modulate the transmitted laser beam. The light modulation unit 640 may include a light modulation device 642, an optical dumper 644, and a cooling device 646.

The light modulation device 642 can modulate the distribution of the laser beam that is generated by the laser source 110. In this case, changing the distribution of a laser beam may mean forming laser beam distribution corresponding to the emission distribution of a laser beam to be emitted to a substrate W.

The light modulation device 642 may be a Digital Micro-mirror Device (DMD).

That is, the light modulation unit 640 may be a DMD unit including a Digital Micro-mirror Device (DMD).

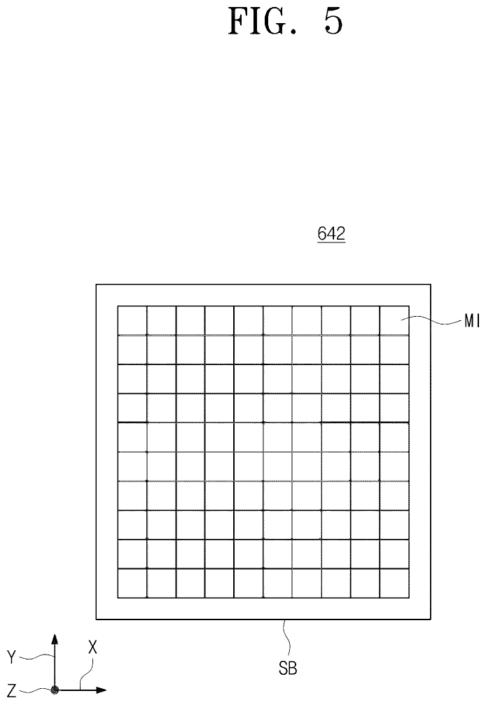

FIG. 5 is a view schematically showing the appearance of the light modulation device. The light modulation device 642 may include a board substrate SB and a plurality of micromirrors MI. Electrodes corresponding to the plurality of micromirrors MI, respectively, may be installed on the board substrate SB. The control unit 30 can transmit a digital signal of “0” or “1” to the electrodes installed on the board substrate SB. The micromirrors MI may be configured to be rotatable. The micromirrors MI can be configured to be rotatable around a direction that is parallel with a plane passing through the first direction X, the second direction Y, or the first direction X and the second direction Y. A micromirror MI corresponding to an electrode receiving a digital signal of “0” can become an Off state and a micromirror MI corresponding to an electrode receiving a digital signal of “1” can become an On state. A micromirror MI in the On state can emit a laser beam to a substrate W and a laser beam reflected by a micromirror MI in the Off state may not be emitted to a substrate W.

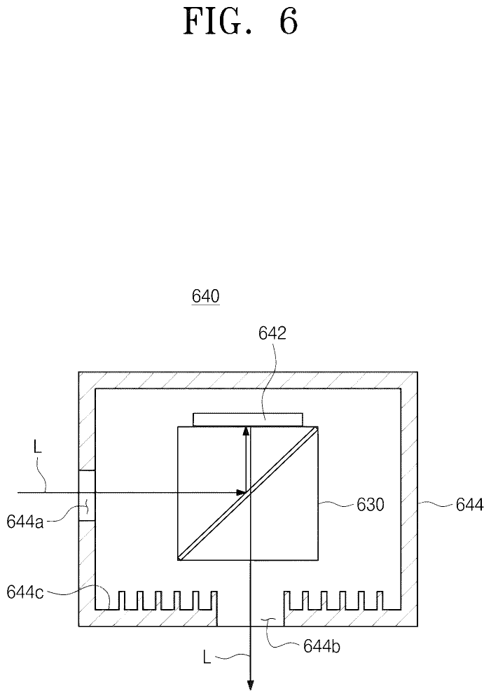

FIG. 6 is a view showing that light is output from the light modulation device. In FIG. 6, for the convenience of description, the traveling path of light that is reflected by any one micromirror MI of micromirrors MI is shown. Referring to FIG. 2, FIG. 5, and FIG. 6, a micromirror MI in the On state can transmit light to a substrate W through the imaging unit 650 to be described below.

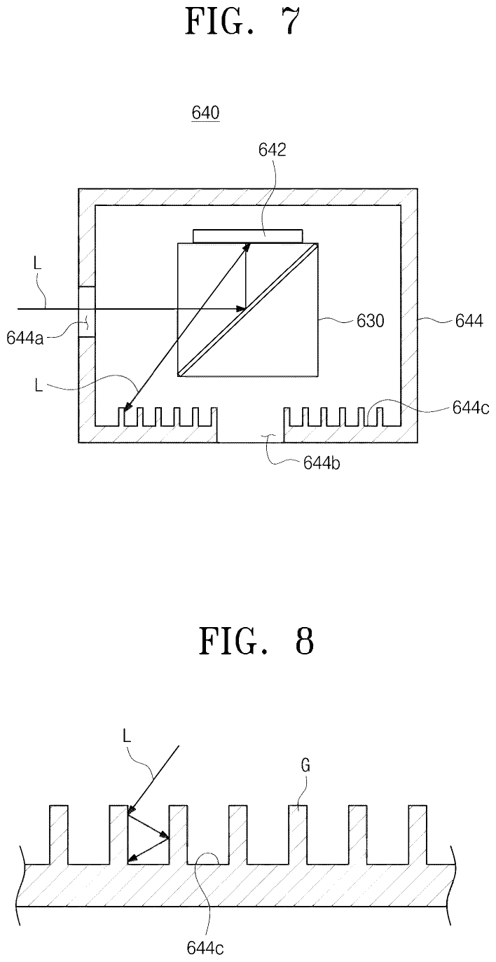

FIG. 7 is a view showing that light output from the light modulation device is removed at an optical dumber. In FIG. 7, for the convenience of description, the traveling path of a laser beam that is reflected by any one micromirror MI of micromirrors MI is shown. Referring to FIG. 2, FIG. 5, and FIG. 7, a micromirror MI in the Off state may not transmit a laser beam to a substrate W by reflecting the laser beam. In detail, micromirrors MI are configured to be rotatable, as described above. A micromirror MI in the Off state may make light not be transmitted to a substrate W by changing the traveling path of the laser beam received from the laser source 110 by rotating. The laser beam that is discharged from the micromirror MI in the Off state may become extinct by being emitted to the inner surface of the optical dumber 644 without passing through a second hole 644b of the optical dumper 644 to be described below.

FIG. 8 is a view for explaining the principle that light is removed at an optical dumper. Referring to FIG. 2 and FIG. 8, the optical dumber 644 may have a box shape having an internal space. The optical dumber 644 may be made of a material that can remove a laser beam by absorbing it such as synthetic resin. The prism optical device 630 may be disposed in the internal space of the optical dumber 644. The light modulation device 642 may be disposed in the internal space of the optical dumber 644 or may be installed outside the optical dumber 644.

A first hole 644a and a second hole 644b may be formed at the optical dumber 644. The first hole 644a may be formed on a side of the optical dumber 644. The first hole 644a may be a hole through which a laser beam generated by the laser source 110 and converted through the beam shaper 620 passes. The second hole 644b may be a hole through which the laser beam modulated by the light modulation device 641 passes. The second hole 644b may be formed on the lower portion of the optical dumber 644.

Grooves G may be formed on the inner surface 644c of the optical dumber 644. The grooves G formed on the inner surface 644c of the optical dumber 644 may be configured to be able to absorb the light reflected by a micromirror MI in the Off state. In detail, when a laser beam is transmitted to the grooves G, the laser beam can be removed by being reflected several times at the grooves G. The laser beam can be removed while being reflected several time at the grooves G and losing energy to the optical dumber 644. In FIG. 2 and FIG. 8, it is exemplarily shown that grooves G are formed only on the lower portion of the optical dumber 644, but the present invention is not limited thereto and grooves G may be formed on the entire inner surface 644c of the optical dumber 644.

Referring to FIG. 2 again, since the optical dumber 644 removes a laser beam, the temperature of the optical dumber 644 may be increased. Accordingly, the light modulation unit 640 according to an embodiment of the present invention may include the cooling device 646 that cools the optical dumber 644. The cooling device 646 may be a fan that generates airflow for cooling the optical dumber 644.

The imaging unit 650 can emit the laser beam modulated and output from the light modulation unit 640 and having passed through the prism optical device 530 to a substrate W by adjusting the laser beam to correspond to an area to which the laser beam is emitted. The imaging unit 650 includes a plurality of lenses that can adjust the size of a laser beam, and can adjust the profile of a laser that is emitted to a substrate W by increasing or decreasing the diameter of a laser beam. The imaging unit 650 can adjust a laser beam into a large-area laser beam having a size corresponding to a substrate W.

The imaging unit 650 may include a component that removes a noise pattern from refractive patterns output from the light modulation unit 640. For example, the imaging unit 650 may include a spatial filter.

The imaging unit 650 includes an emission lens 652. A laser beam modulated and output from the light modulation unit 640 and having passed through the prism optical device 530 is adjusted by the imaging unit 650 and emitted to a substrate W through the emission lens 652.

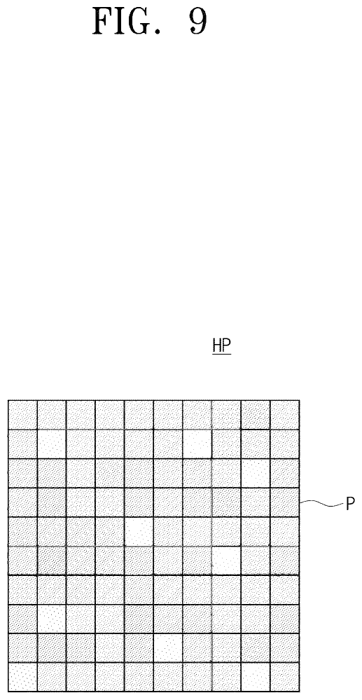

FIG. 9 is a view for explaining an emission pattern of light that is output from the light modulation unit. Referring to FIG. 2, FIG. 5, and FIG. 9, as described above, micromirrors MI can be changed between the On state and the Off state. The state change of each micromirror MI between the On state and the Off state can be made within a very short time. By On-Off state change of each micromirror MI, the light modulation unit 640 can form very various emission patterns HP. For example, in FIG. 9, the amount of heat that is transmitted to a substrate W per unit time by a laser beam reflected by each micromirror MI for unit time (e.g., 1 second) is shown. The emission pattern HP may be composed of a plurality of patterns P corresponding to micromirrors MI, respectively. In order to increase the amount of heat that is transmitted to a substrate W per unit time from each micromirror MI, it is possible to maintain the On state of the micromirrors MI per unit time for a long time and maintain the Off state per unit time for a short time. In order to decrease the amount of heat that is transmitted to a substrate W per unit time from each micromirror MI, it is possible to maintain the On state of the micromirrors MI per unit time for a short time and maintain the Off state per unit time for a long time.

The laser beam modulated by the light modulation unit 640 and adjusted by the imaging unit 650 is emitted to a substrate W.

The components of the apparatus 100 for treating a substrate can be controlled by a control unit (not shown). A control unit (not shown) can control the entire operation of the apparatus 1000 for treating a substrate. The control unit (not shown) may include a Central Processing Unit (CPU), a Read Only Memory (ROM) and a Random Access Memory (RAM). The CPU performs desired treatment such as etching treatment in accordance with various recipes stored in memory region of them.

Control information of the apparatus for process conditions is input in the recipes. Meanwhile, recipes showing programs or treatment conditions may be stored in a non-transitory computer-readable medium. The non-transitory computer-readable medium is not a medium that stores data for a short time such as a cache and a memory, but a medium that can semipermanently store data and can be read out by a computer. In detail, the various applications or programs described above may be stored and provided in a non-transitory computer readable medium such as a CD, a DVD, a hard disk, a blueray disc, a USB, a memory card, and a ROM.

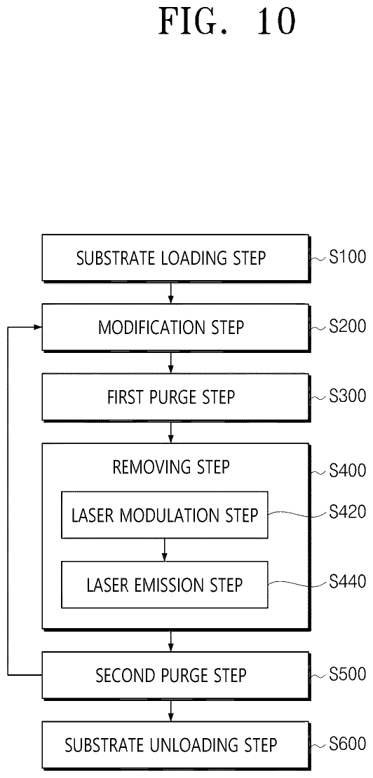

FIG. 10 is a flowchart showing a method of processing a substrate as an embodiment that uses the apparatus of processing a substrate of the present invention.

Referring to FIG. 10, the method of processing a substrate according to an embodiment of the present invention includes a substrate loading step S100, a modification step S200, a first purge step S300, a removing step S400, a second purge step S500, and a substrate unloading step S600. Further, the removing step S400 includes a laser modulation step S420 and a laser emission step S440.

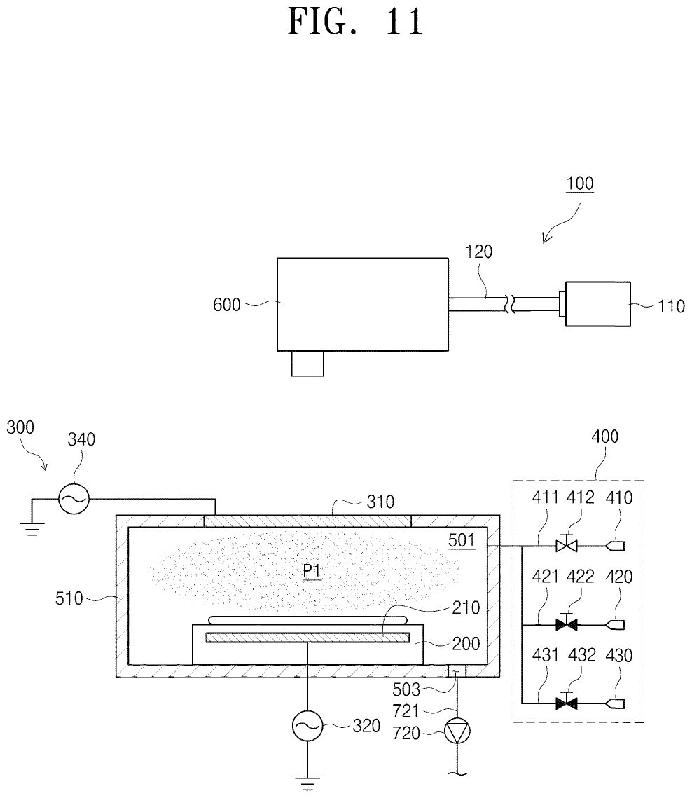

Hereafter, the method of processing a substrate using the apparatus of processing a substrate according to an embodiment of the present invention is described with reference to FIG. 11 to FIG. 15.

The substrate loading step S100 of FIG. 10 is performed. A substrate W is loaded into the internal space 501 of the process chamber 510. The substrate W undergoes a step of inspecting the thickness of the substrate W before it is loaded in to the internal space 501, whereby it is possible to create a distribution map of a thin film thickness for the substrate W. The distribution map of a thin film thickness for a substrate W includes thickness data for each of positions on the substrate, that is, each of regions on the substrate. A step of treating a substrate W using a distribution map of a thin film thickness for the substrate W is described hereafter.

FIG. 11 is a view illustrating the state of the apparatus when the modification step of FIG. 10 is performed.

Referring to FIG. 11, in the modification step S200, a first gas is supplied to the internal space 501 and the first gas is excited by plasma. The plasma excited from the first gas is adsorbed to the surface of a substrate W and the surface of the substrate W is called modification. The modification step S200 is performed when a substrate W is at first temperature. The first temperature is temperature at which plasma excited from the first gas is maximally adsorbed to the surface of a substrate W. For example, the first temperature may be around 20° C. Since a substrate W is treated at temperature at which adsorption on the surface of the substrate W is maximized, the time for an adsorption reaction can be reduced. For example, an adsorption reaction may be performed within 1 second.

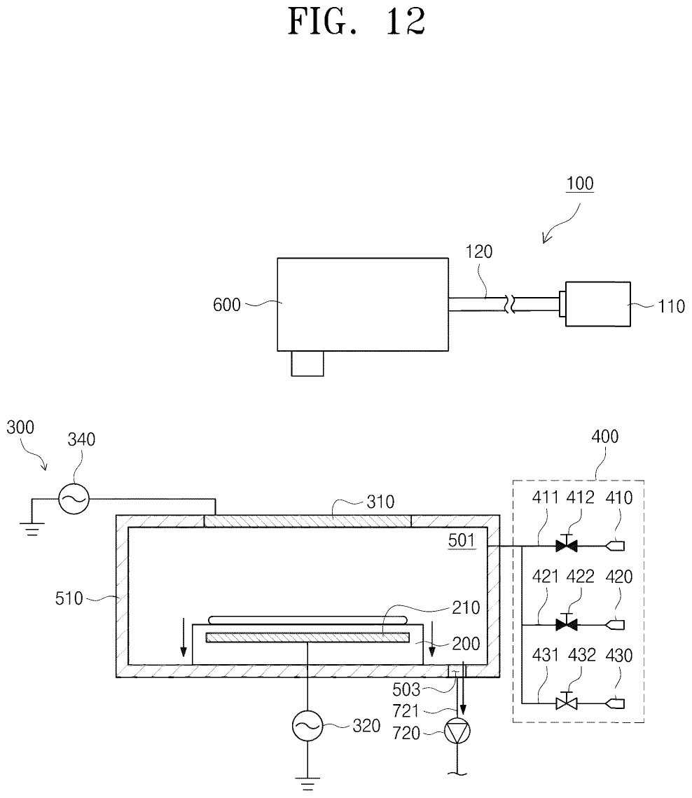

FIG. 12 is a view illustrating the state of the apparatus when the first purge step of FIG. 10 is performed.

Referring to FIG. 12, when the modification step S200 is finished, the first purge step S300 is performed. In the first purge step S300, a third gas is supplied to the internal space 501. The third gas may be nitrogen. Further, the atmosphere of the internal space 501 is exhausted. Process gases and process byproducts remaining in purging in the internal space 501 are exhausted through the exhaust hole 503. The first purge step S300 may be performed around about 5 seconds, but it is not limited thereto and is sufficient as long as the remaining process gases and process byproducts are properly exhausted.

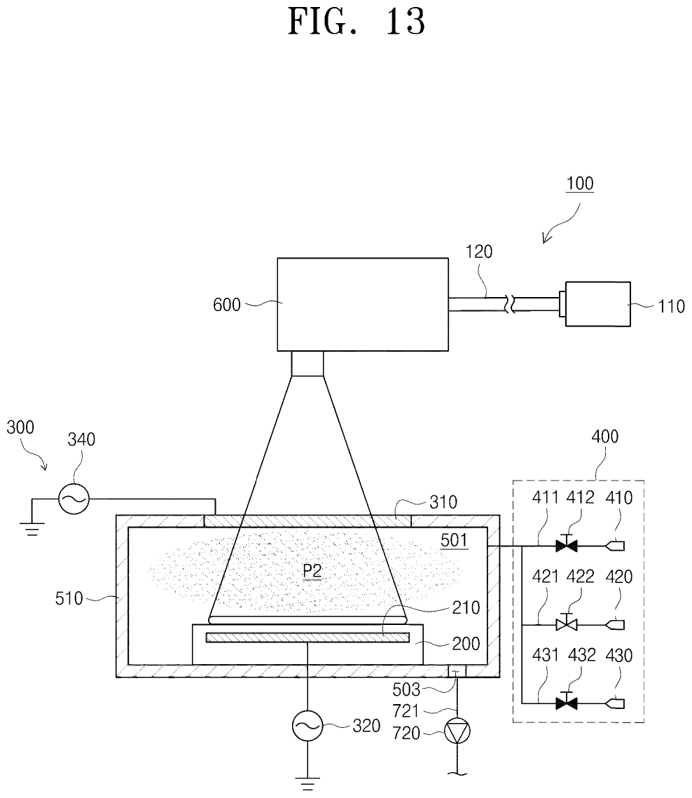

FIG. 13 is a view illustrating the state of the apparatus when the removing step of FIG. 10 is performed.

Referring to FIG. 13, the removing step S400 is performed after the first purge step S300. In the removing step S400, a second gas is supplied to the internal space 501 and the second gas is excited by plasma. The plasma excited from the second gas removes the surface of the modified substrate W.

The removing step S400 includes a laser modulation step S420 and a laser emission step S440.

In the removing step S400, the surface of the substrate W is heated by a laser beam that is emitted by the laser emission unit 100. The laser beam applies heat energy to the substrate W. The laser beam is modulated and then emitted by the light modulation device 642. That is, the laser beam that is emitted to the substrate W is modulated through the laser modulation step S420 and then emitted to the substrate W in the laser emission step S440.

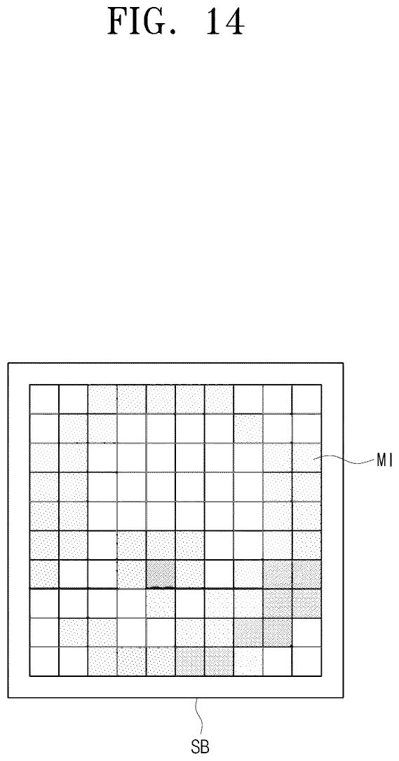

FIG. 14 shows an embodiment of an emission pattern of a laser beam modulated in the laser modulation step of FIG. 10.

In the laser modulation step S420, the light modulation unit 640 can change the shape of the emission pattern of a laser by adjusting the On/Off states of the micromirrors MI described above. The emission pattern of the laser modulated through the light modulation unit 640 can reflect a distribution map created in thickness inspection of the substrate W performed before the substrate W is loaded into the internal space 501 of the process chamber 510.

Referring to FIG. 14, the amount of heat that is transmitted to a substrate W per unit time by a laser beam reflected by micromirrors MI for an emission pattern (unit time (e.g., 1 second)) is shown. A laser beam having the emission pattern shown in FIG. 14 is emitted to a substrate W in correspondence to a distribution map of a thin film thickness for each position on a substrate W, it is possible to adjust the amount of heating in correspondence to the thin film thickness according to positions on the substrate W, that is, the thin film thickness of the substrate W in each local region on the substrate W.

The laser beam modulated in the laser modulation step S420 is emitted to the substrate W in the laser emission step S440.

In this case, the imaging nit 650 of the laser emission unit 100 can adjust the laser beam into a large-area laser beam having a size corresponding to the substrate W. The laser beam that has passed through the imaging nit 650 of the laser emission unit 100 can be emitted to the entire region of the substrate W. That is, the laser emission unit 100 can emit a laser beam to the entire region of the substrates W.

When a laser beam is substrate to the substrate W, products produced on the surface of the substrate W can be physically removed from the surface of the substrate W. The entire substrate W is etched, and the substrate W may be further etched by selectively heating predetermined regions of the substrate W, depending on the emission pattern of the laser beam. The degree of etching depends on the amount of heat transmitted by a laser beam per unit time and the light modulation unit 640 of the present invention can form emission patterns having various shapes, so it is possible to control etching for a substrate W in various ways. Accordingly, it is possible to adjust the amount of heating in correspondence to the thin film thickness of a substrate W for each local region of the substrate W. For example, a micromirror MI corresponding to an emission pattern that is emitted to a region having a relatively large thin film thickness of the regions of a substrate W maintains the On state per unit time for a long time and the Off state per unit time for a short time, whereby it is possible to increase the amount of heat that is transmitted to the substrate W such that etching is made well. Further, a micromirror MI corresponding to an emission pattern that is emitted to a region having a relatively small thin film thickness of the regions of a substrate W maintains the On state per unit time for a short time and the Off state per unit time for a long time, whereby it is possible to decrease the amount of heat that is transmitted to the substrate W such that etching is less made.

When the removing step S400 is finished, the second purge step S500 is performed.

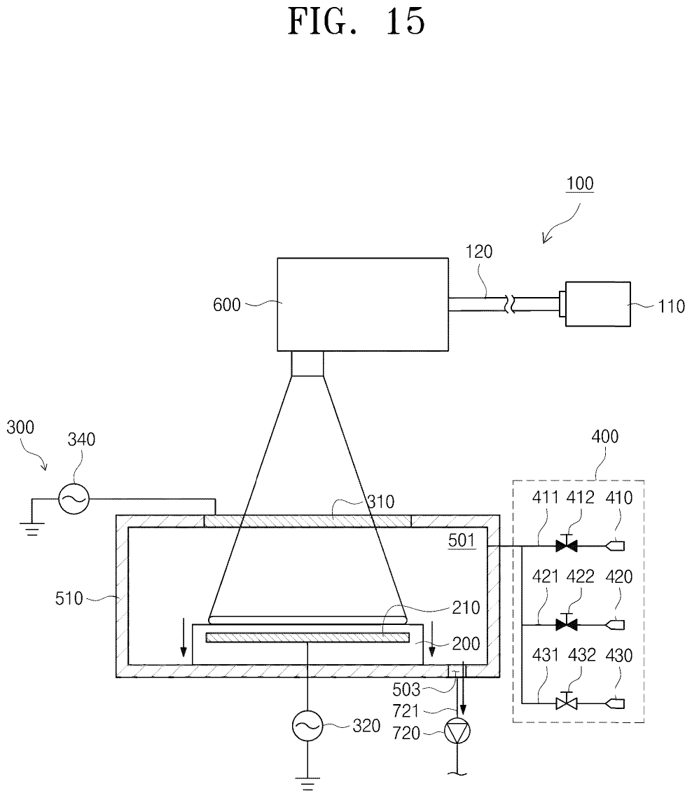

FIG. 15 is a view illustrating the state of the apparatus when the second purge step of FIG. 10 is performed.

FIG. 15 is referred to. When the removing step S400 is finished, the third gas is supplied to the internal space 501. The third gas may be nitrogen. Further, the atmosphere of the internal space 501 is exhausted. Process gases and process byproducts remaining in purging in the internal space 501 are exhausted through the exhaust hole 503. The purge step may be performed around about 5 seconds, but it is not limited thereto and is sufficient as long as the remaining process gases and process byproducts are properly exhausted.

The modification step S200—first purge step S300—removing step S400—second purge step S500 may be repeated multiple times until a desired etching condition is achieved.

When etching of the substrate W is finished, the substrate unloading step S600 is performed. The substrate W is unloaded out of the process chamber 510 from the internal space 501 of the process chamber 510.

According to the embodiment of the present invention described above, the laser emission unit 100 forms different emission patterns of a laser that is emitted to each of local regions of a substrate W, whereby it is possible to selectively adjust the amount of heat that heats each of the regions of the substrate W. It is possible to partially adjust the amount of etching by adjusting the amount of heat that heats each of regions of a substrate and it is possible to adjust the amount of heating and the amount of etching for each of local regions of the substrate W by reflecting a distribution map of a thin film thickness for the substrate W.

Accordingly, even though the thin film thickness of a substrate W forms asymmetric distribution, it is possible to perform etching such that a uniform thin film is formed on the substrate W by selectively heating the substrate W.

In the embodiment described above, it was shown and described that a substrate W is heated using the laser emission unit 100 in the removing step S400, but the present invention is not limited thereto. For example, in the modification step S200 as well, it is possible to selectively heat a substrate W by modulating and emitting a laser to the substrate W using the laser emission unit 100.

It is exemplarily described in the above embodiment that the apparatus of processing a substrate of the present invention performs a so-called Atomic layer etching (ALE) process using the laser emission unit 100, but the apparatus of processing a substrate of the present invention can be applied also to annealing a substrate W. Further, the apparatus can be applied to another high-temperature heating process not described.

The laser emission unit 100 of the present invention can adjust the laser beam into a large-area laser beam having a size corresponding to the substrate W through the imaging nit 650. Further, since the light modulation unit 640 forms different emission patterns of a laser beam for each of local regions of a substrate W, it is possible to selectively adjust the amount of heat that heats each region of the substrate and it is possible to partially adjust the amount of etching by adjusting the amount of heat that heats each region of the substrate W. Accordingly, the laser emission unit 100 of the present invention and the method of processing a substrate according to the laser emission unit 100, that is, the process including the laser modulation step S420 and the laser emission step S440 is not limited to etching of a substrate W through an ALE process and can be modified and applied in various ways to processes of heating a substrate W such as a dry etch process or dry cleaning using plasma, ashing, etc.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. An apparatus of processing a substrate, the apparatus comprising:
a chamber providing a treatment space;
a substrate supporting unit provided in the treatment space;
a gas supply unit introducing gas into the treatment space;
a plasma source providing energy that excites the gas introduced in the treatment space using plasma;
an exhaust unit exhausting an atmosphere in the treatment space out of the treatment space; and
a laser emission unit disposed above the supporting unit and emitting a laser beam to a substrate placed on the supporting unit,
wherein the laser emission unit comprises:
a laser source generating the laser beam; and
a Digital Micro-mirror Device (DMD) unit that is a light modulation unit modulating the laser beam generated from the laser source,
wherein the DMD unit comprises:
micromirrors provided to be rotatable; and
a board substrate on which the micromirrors are installed.

2. The apparatus of claim 1, wherein the laser emission unit further comprises an imaging unit adjusting and emitting the laser beam modulated by the DMD unit to the substrate to correspond to an area to which the laser beam is emitted.

3. The apparatus of claim 2, wherein the laser emission unit further comprises a beam shaper converting the type of the laser beam generated by the laser source, and
the beam shaper converts the type of the laser beam and then transmits the laser beam to the DMD unit.

4. The apparatus of claim 2, further comprising:
a window provided on a top of the chamber;
an upper electrode stacked on the window;
a lower electrode provided lower than the substrate; and
a high-frequency power supply connected with any one or more of the upper electrode and the lower electrode,
wherein the upper electrode is a transparent electrode, and
the laser emission unit is provided above the window.

5. The apparatus of claim 4, wherein the window is made of a quartz material.

6. The apparatus of claim 4, further comprising a control unit
wherein the control unit controls each of the micromirrors of the DMD unit to selectively switch an On state in which each of the micromirror reflects the laser beam to the substrate and an Off state in which each of the micromirror dumps the laser beam so that heat energy required for each region of the substrate can be transmitted by emitting the laser beam to the substrate.

7. The apparatus of claim 6, wherein the control unit performs control to perform a removing step in which the gas supply unit introduces a process gas into the treatment space, the plasma source excites the introduced process gas with plasma, and then the laser emission unit heats the substrate by emitting the laser beam to the substrate.

8. The apparatus of claim 7, wherein, in the removing step, the laser emission unit emits the laser beam to an entire region of the substrate and the DMD unit forms different emission patterns of the laser beam that is emitted to each of local regions of the substrate such that the amount of heat that heats each of the regions of the substrate is selectively adjusted.

9. The apparatus of claim 8, wherein, in the removing step, the emission pattern of the laser beam is formed by reflecting thickness data for each of the regions of the substrate.

10.-15. (canceled)

16. An apparatus of processing a substrate, the apparatus comprising:
a chamber providing a treatment space;
a substrate supporting unit provided in the treatment space;
a gas supply unit introducing gas into the treatment space;
a plasma source providing energy that excites the gas introduced in the treatment space using plasma;
an exhaust unit exhausting an atmosphere in the treatment space out of the treatment space;
a window provided on a top of the chamber;
an upper electrode stacked on the window;
a lower electrode provided lower than the substrate;
a high-frequency power supply connected with any one or more of the upper electrode and the lower electrode; and
a laser emission unit disposed above the window and emitting a laser beam to a substrate placed on the supporting unit,
wherein the laser emission unit comprises:
a laser source generating the laser beam;
a Digital Micro-mirror Device (DMD) unit that is a light modulation unit modulating the laser beam generated from the laser source;
an imaging unit adjusting and emitting the laser beam modulated by the DMD unit to the substrate to correspond to an area to which the laser beam is emitted; and
a beam shaper converting the type of the laser beam generated by the laser source,
wherein the DMD unit comprises:
micromirrors provided to be rotatable; and
a board substrate on which the micromirrors are installed, and
the upper electrode is a transparent electrode.

17. The apparatus of claim 16, further comprising a control unit,
wherein the control unit controls each of the micromirrors of the DMD unit to selectively switch an On state in which each of the micromirror reflects the laser beam to the substrate and an Off state in which each of the micromirror dumps the laser beam so that heat energy required for each region of the substrate can be transmitted by emitting the laser beam to the substrate.

18. The apparatus of claim 17, wherein the control unit performs control to perform:
a modification step in which the gas supply unit introduces a first process gas into the treatment space and the introduced first process gas is excited with plasma by controlling the plasma source, thereby treating the substrate;
a first purge step in which the gas supply unit introduces a third process gas into the treatment space and the treatment space is exhausted by controlling the exhaust unit;
a removing step in which the gas supply unit introduces a second process gas into the treatment space, the introduced second process gas is excited with plasma by controlling the plasma source, and then the laser emission unit heats the substrate by emitting the laser beam to the substrate; and
a second purge step in which the gas supply unit introduces the third process gas into the treatment space and the treatment space is exhausted by controlling the exhaust unit, and
the modification step, the first purge step, the removing step, and the second purge step are sequentially performed.

19. The apparatus of claim 18, wherein, in the removing step, the laser emission unit emits the laser beam to an entire region of the substrate and the DMD unit forms different emission patterns of the laser beam that is emitted to each of local regions of the substrate such that the amount of heat that heats each of the regions of the substrate is selectively adjusted.

20. The apparatus of claim 19, wherein, in the removing step, the emission pattern of the laser beam is formed by reflecting thickness data for each of the regions of the substrate.
